(19) United States
(12) Patent Application Publication
(10) Pub. No.: US 2014/0173239 A1
(43) Pub. Date: Jun. 19, 2014

(54) REFRESHING OF MEMORY BLOCKS USING ADAPTIVE READ DISTURB THRESHOLD

(71) Applicant: APPLE INC., Cupertino, CA (US)

(72) Inventor: Asaf Schushan, Ramat Hasharon (IL)

(73) Assignee: APPLE INC., Cupertino, CA (US)

(21) Appl. No.: 13/720,144

(22) Filed: Dec. 19, 2012

(51) Int. Cl. G11C 16/34; G06F 12/02

(52) U.S. Cl. CPC G11C 16/3427; G06F 12/02
USPC 711/165; 365/185.02

(57) ABSTRACT

A method includes storing data in a memory that includes multiple memory blocks. A level of distortion that affects a given memory block of the memory is estimated. An adaptive read disturb threshold is set for the given memory block as a function of the estimated level of distortion. Upon detecting that a number of read operations performed in the given memory block exceeds the read disturb threshold, the data stored in the memory block is copied to an alternative storage location.

### FIELD OF THE INVENTION

The present invention relates generally to data storage, and particularly to methods and systems for refreshing of memory blocks.

### BACKGROUND OF THE INVENTION

Analog memory cells, such as Flash cells, may be affected by various types of impairments or distortion. Various techniques are known in the art for refreshing

Flash memory in order to reduce the distortion levels. For example, U.S. Pat. No. 7,778,078, whose disclosure is incorporated herein by reference, describes a memory system that includes a Flash memory, a memory and a controller. The Flash memory stores data. The memory stores a read count table that indicates the number of times of data read from the Flash memory. The controller reads out the data from the Flash memory, updates the read count table when the controller performs reading out the data from the Flash memory, and refreshes the Flash memory based on the read count table.

As another example, U.S. Patent Application Publication 2009/0172267, whose disclosure is incorporated herein by reference, describes a Flash memory device that includes a Flash memory, a refresh management table and a controller. The Flash memory stores physical data blocks. The refresh management table stores indications of the number of times each individual physical data block has been read. The controller is responsive to read and erase control signals from a source external to the Flash memory device, and to the stored indications of the refresh management table for controlling reading, erasing and refreshing of the individual physical data blocks. In response to the number of times each individual physical data block has been read being equal to or exceeding a limit value, the controller refreshes the individual physical data block associated with the indication equaling or exceeding the limit value.

### SUMMARY OF THE INVENTION

A method includes storing data in a memory that includes multiple memory blocks. A level of distortion that affects a given memory block of the memory is estimated. An adaptive read disturb threshold is set for the given memory block as a function of the estimated level of distortion. Upon detecting that a number of read operations performed in the given memory block exceeds the read disturb threshold, the data stored in the memory block is copied to an alternative storage location.

In some embodiments, estimating the level of distortion includes assessing a number of programming and erasure cycles applied to the given memory block. In other embodiments, estimating the level of distortion includes assessing a time that elapsed since the data was stored in the given memory block.

In a disclosed embodiment, detecting that the number of read operations exceeds the read disturb threshold includes incrementing a counter for each of the read operations performed in the given memory block, and comparing the counter to the read disturb threshold. In an example embodiment, the method includes estimating a second level of distortion that affects a second memory block of the memory, different from the given memory block; setting a second adaptive read disturb threshold for the second memory block depending on the estimated second level of distortion, such that the second read disturb threshold differs from the read disturb threshold of the given memory block; and, upon detecting that the number of read operations performed in the second memory block exceeds the second read disturb threshold, copying the data stored in the second memory block to a second alternative storage location.

In another embodiment, setting the read disturb threshold includes estimating a maximum number of the read operations that still enables successful readout of the stored data in the presence of the estimated level of distortion, and setting the read disturb threshold based on the maximum number. In yet another embodiment, detecting that the number of read operations exceeds the read disturb threshold and copying the data are performed after performing a read operation from the given memory block. Alternatively, detecting that the number of read operations exceeds the read disturb threshold and copying the data may be performed by a background task that scans the memory blocks of the memory.

There is additionally provided, in accordance with an embodiment of the present invention, apparatus including an interface and a processor. The interface is configured to communicate with a memory that includes multiple memory blocks. The processor is configured to store data in the memory, to estimate a level of distortion that affects a given memory block of the memory, to set an adaptive read disturb threshold for the given memory block as a function of the estimated level of distortion, and, upon detecting that a number of read operations performed in the given memory block exceeds the read disturb threshold, to copy the data stored in the memory block to an alternative storage location.

There is also provided, in accordance with an embodiment of the present invention, apparatus including a memory and a processor. The memory includes multiple memory blocks. The processor is configured to store data in the memory, to estimate a level of distortion that affects a given memory block of the memory, to set an adaptive read disturb threshold for the given memory block as a function of the estimated level of distortion, and, upon detecting that a number of read operations performed in the given memory block exceeds the read disturb threshold, to copy the data stored in the memory block to an alternative storage location.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a memory system, in accordance with an embodiment of the present invention; and

FIG. 2 is a flow chart that schematically illustrates a method for refreshing Flash memory blocks, in accordance with an embodiment of the present invention.

### DETAILED DESCRIPTION OF EMBODIMENTS

### Overview

Data is typically stored in analog memory cells by programming the cells with analog values that represent the data. In Flash memory, for example, the programming operation sets the levels of electrical charge stored in the cells, and thus the cell threshold voltages. Data readout from analog memory cells typically involves sensing the analog values stored in the cells so as to reconstruct the data.

The analog values stored in analog memory cells may be distorted by various types of impairments. Some types of impairments develop or accumulate over time and usage. Examples of such impairments are referred to as retention (drifting of the analog values with time), endurance (deterioration of the physical media of the memory cells due to excessive programming and erasure cycling) and read disturb (distortion of the analog values caused by read operations applied to other cells). The combined effect of these impairments is that the readout performance of analog memory cells deteriorates with time and usage, leading to read errors and even potential loss of data.

Embodiments of the present invention that are described herein provide improved methods and systems for mitigating memory cell impairments. In some embodiments, a processor stores data in a memory that comprises analog memory cells arranged in memory blocks. Among other management functions, the processor refreshes a memory block when the number of read operations from the block exceeds a certain read disturb threshold defined for the block. Refreshing typically comprises copying the data from the memory block to an alternative storage location, thereby resetting the read disturb level.

In the disclosed embodiments, the read disturb threshold is set and adapted independently per memory block, depending on the actual level of distortion in the block. For a given memory block, the processor estimates the level of distortion (e.g., retention and/or endurance) affecting the block, and adapts the read disturb threshold (i.e., the number of read operations from the block that trigger a refresh operation) as a function of the estimated distortion.

Typically, a memory block that has low distortion (e.g., a fresh block that was programmed recently and was not subjected to many erasure cycles) is able to sustain a large number of read operations and still enable successful data readout. Therefore, when the estimated distortion is low, the processor will typically set a high read disturb threshold. As a result, the next refreshing operation will be delayed until it is needed, avoiding unnecessary copy operations. An old or heavily-used memory block, on the other hand, will typically be refreshed after a smaller number of read operations.

In summary, the adaptive refreshing techniques described herein match the read disturb threshold to the actual level of distortion that affects each memory block, as opposed to using a fixed worst-case threshold for all the blocks. As a result, the number of copy operations is reduced without degrading readout performance. The reduction in the number of copy operation helps to improve the storage throughput of the memory and extend its lifetime.

### System Description

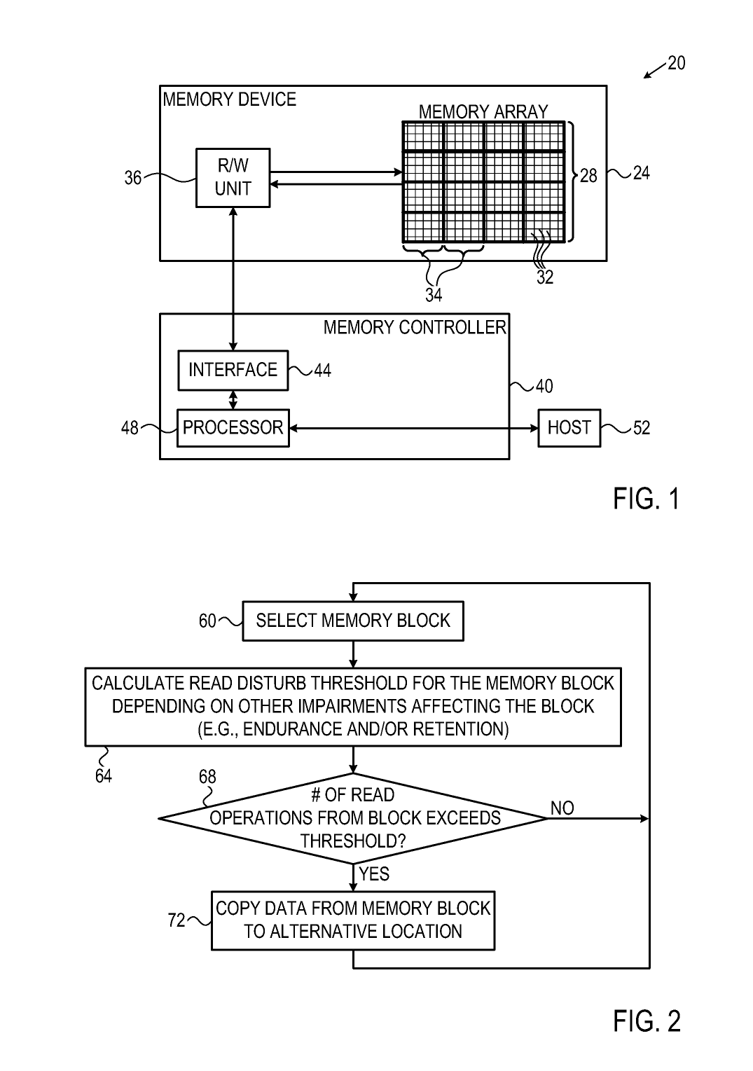

FIG. 1 is a block diagram that schematically illustrates a memory system 20, in accordance with an embodiment of the present invention. System 20 can be used in various host systems and devices, such as in computing devices, cellular phones or other communication terminals, removable memory modules (sometimes referred to as “USB Flash Drives”), Solid State Disks (SSD), digital cameras, music and other media players and/or any other system or device in which data is stored and retrieved.

System 20 comprises a memory device 24, which stores data in a memory cell array 28. The memory array comprises multiple memory blocks 34. Each memory block 34 comprises multiple analog memory cells 32. In the context of the present patent application and in the claims, the term “analog memory cell” is used to describe any memory cell that holds a continuous, analog value of a physical parameter, such as an electrical voltage or charge. Array 28 may comprise analog memory cells of any kind, such as, for example, NAND, NOR and Charge Trap Flash (CTF) Flash cells, phase change RAM (PRAM, also referred to as Phase Change Memory—PCM), Nitride Read Only Memory (NROM), Ferroelectric RAM (FRAM), magnetic RAM (MRAM) and/or Dynamic RAM (DRAM) cells. Although the embodiments described herein refer mainly to two-dimensional (2D) cell connectivity schemes, the disclosed techniques are applicable to three-dimensional (3D) connectivity schemes, as well.

The charge levels stored in the cells and/or the analog voltages or currents written into and read out of the cells are referred to herein collectively as analog values, analog storage values or storage values. The storage values may comprise, for example, threshold voltages or any other suitable kind of storage values. System 20 stores data in the analog memory cells by programming the cells to assume respective programming states, which are also referred to as programming levels. The programming states are selected from a finite set of possible states, and each programming state corresponds to a certain nominal storage value. For example, a 3 bit/cell MLC can be programmed to assume one of eight possible programming states by writing one of eight possible nominal storage values into the cell.

Memory device 24 comprises a reading/writing (R/W) unit 36, which converts data for storage in the memory device to analog storage values and writes them into memory cells 32. In alternative embodiments, the R/W unit does not perform the conversion, but is provided with voltage samples, i.e., with the storage values for storage in the cells. When reading data out of array 28, R/W unit 36 converts the storage values of memory cells into digital samples having a resolution of one or more bits. Data is typically written to and read from the memory cells in groups that are referred to as pages. In some embodiments, the R/W unit can erase a group of cells 32 by applying one or more negative erasure pulses to the cells. Erasure is typically performed in entire memory block units.

The storage and retrieval of data in and out of memory device 24 is performed by a memory controller 40. The memory controller comprises an interface 44 for communicating with memory device 24, and a processor 48 that carries out the various memory management functions. Memory controller 40 communicates with a host 52, for accepting data for storage in the memory device and for outputting data retrieved from the memory device. Memory controller 40, and in particular processor 48, may be implemented in hardware. Alternatively, the memory controller may comprise a microprocessor that runs suitable software, or a combination of hardware and software elements.

The configuration of FIG. 1 is an exemplary system configuration, which is shown purely for the sake of conceptual clarity. Any other suitable memory system configuration can also be used. Elements that are not necessary for understanding the principles of the present invention, such as various interfaces, addressing circuits, timing and sequencing circuits and debugging circuits, have been omitted from the figure for clarity.

Although the example of FIG. 1 shows a single memory device 24, system 20 may comprise multiple memory devices that are controlled by memory controller 40. In the exemplary system configuration shown in FIG. 1, memory device 24 and memory controller 40 are implemented as two separate Integrated Circuits (ICs). In alternative embodiments, however, the memory device and the memory controller may be integrated on separate semiconductor dies in a single Multi-Chip Package (MCP) or System on Chip (SoC), and may be interconnected by an internal bus. Further alternatively, some or all of the memory controller circuitry may reside on the same die on which the memory array is disposed. Further alternatively, some or all of the functionality of memory controller 40 can be implemented in software and carried out by a processor or other element of the host system. In some embodiments, host 44 and memory controller 40 may be fabricated on the same die, or on separate dies in the same device package.

In some embodiments, memory controller 40 comprises a general-purpose processor, which is programmed in software to carry out the functions described herein. The software may be downloaded to the processor in electronic form, over a network, for example, or it may, alternatively or additionally, be provided and/or stored on non-transitory tangible media, such as magnetic, optical, or electronic memory.

In an example configuration of array 28, memory cells 32 are arranged in multiple rows and columns, and each memory cell comprises a floating-gate transistor. The gates of the transistors in each row are connected by word lines, and the sources of the transistors in each column are connected by bit lines. The memory array is typically divided into multiple pages, i.e., groups of memory cells that are programmed and read simultaneously. Pages are sometimes sub-divided into sectors. In some embodiments, each page comprises an entire row of the array. In alternative embodiments, each row (word line) can be divided into two or more pages. For example, in some devices each row is divided into two pages, one comprising the odd-order cells and the other comprising the even-order cells.

Typically, memory controller 40 programs data in page units, but erases entire memory blocks 34. Typically although not necessarily, a memory block is on the order of 10⁶ memory cells, whereas a page is on the order of 10³-10⁴ memory cells.

### Refreshing of Memory Blocks Using an Adaptive Read Disturb Threshold

In a typical memory device, the analog values stored in memory cells 32 may be distorted by various types of impairments. The distortion may be comprise, for example, retention-related distortion, endurance-related distortion, read disturb, and often a combination of all three types.

Retention-related distortion is typically caused by gradual leakage of electrical charge from the memory cells, causing a drift of the analog values with time. Endurance-related distortion is caused by gradual degradation of the physical media of the memory cells due to excessive programming and erasure cycling. Read disturb distortion is caused by read operations applied to other cells. Other types of distortion may also exist.

Two relevant properties of the above-described distortion mechanisms are that they all develop or accumulate gradually over time, and that different memory blocks 34 may experience different levels of distortion of different types.

The retention, endurance and read disturb effects cause read errors, and the number or likelihood of errors therefore increases with time and usage. The readout performance (e.g., Bit Error Rate—BER) in a given memory block is typically a function of all three effects.

It is usually possible to define an operating point in which the degradation in readout performance no longer enables successful readout of data. For example, when the stored data is encoded with an Error Correction Code (ECC) that is able to correct t errors per code word, distortion that is likely to cause more than t errors per code word is not tolerable. Since different memory blocks experience different levels of distortion, different memory blocks will typically reach the maximum tolerable degradation at different times. Moreover, the same overall degradation may be caused by different combinations of distortion types (e.g., small endurance and high retention, and high endurance and small retention).

In some embodiments, processor 48 of memory controller 40 refreshes memory blocks 34 from time to time, in order to reduce read disturb effects. In a refresh operation, processor 48 typically copies the data from the memory block being refreshed to an alternative storage location. The alternative location typically comprises an erased memory block that is ready for new programming. By refreshing the memory block in this manner, the level of read disturb that affects the data is reset.

As explained above, read disturb in a given memory block is caused by read operations applied to the block. Therefore, processor 48 typically decides to refresh a given memory block when the number of read operations from the block reaches a certain threshold. This threshold is referred to herein as a read disturb threshold. After refreshing the memory block, the count of read operations is typically reset.

In the disclosed embodiments, the read disturb threshold is set and adapted independently per memory block. The rationale behind this technique is that different memory blocks may experience different levels of distortion (e.g., retention and endurance), and therefore may be able to sustain different levels of read disturb for the same performance requirement.

Typically, processor 48 estimates the level of distortion (e.g., retention and/or endurance) affecting each memory block, and adapts the read disturb threshold for that block as a function of the estimated distortion.

When using this technique, a memory block having small retention and/or endurance will be refreshed after a larger number of read operations, in comparison with a memory block having high retention and/or endurance. This differentiation enables processor 48 to reduce the number of refresh operations, and thus increase the throughput and lifetime of memory device 24.

FIG. 2 is a flow chart that schematically illustrates a method for refreshing memory blocks 34 in memory device 24, in accordance with an embodiment of the present invention. The method begins with processor 48 selecting a memory block 34, at a block selection step 60.

Processor 48 adapts the read disturb threshold defined for the selected memory block, at a threshold adaptation step 64. Typically, processor 48 estimates the level of distortion (e.g., endurance and/or retention) in the selected memory block, and adapts the read disturb threshold defined for that block based on the estimated distortion level.

Processor 48 may estimate the level of distortion in any suitable way. The level of endurance may be estimated, for example, by counting or otherwise assessing the number of programming and erasure cycles applied to the block. The level of retention may be estimated, for example, by measuring or otherwise assessing the time that elapsed since the block was last programmed.

Processor 48 checks whether the number of read operations performed in the selected memory block exceeds the block's read disturb threshold, at a refresh checking step 68. In an example implementation, with every read operation from the block, processor 48 increments a counter that counts the number of read operations from the block. In step 68, the processor compares the counter value of the selected block to the read disturb threshold. The processor typically maintains similar counters for the different memory blocks.

If step 68 concludes that the read disturb threshold is not yet exceeded, the method loops back to step 60 in which processor 48 selects another memory block for evaluation. Upon detecting at step 68 that the read disturb threshold is exceeded processor 48 refreshes the memory block, at a refreshing step 72. The processor typically copies the data from the selected block to a fresh erased block. The method then loops back to step 60 above.

Processor 48 may scan memory blocks 34, or otherwise select memory blocks for evaluation, in any suitable manner. In some embodiments, processor 48 carries out the method of FIG. 2 after every read operation or after every predefined number of read operations. In alternative embodiments, processor 48 may run a background task that scans memory blocks 34 in some order and applies the method of FIG. 2 to each scanned block. The background task typically executes during time periods in which the memory controller is idle, e.g., not busy performing storage operations for the host.

In various embodiments, processor 48 may set the read disturb threshold in different ways. For example, processor 48 may estimate the maximum number of read operations from the block that will still enable successful data readout from the block in the presence of the estimated level of distortion (e.g., retention and endurance). Since the level of retention and endurance varies from one memory block to another, the maximum allowed number of read operations will also vary. The processor typically sets the read disturb threshold at a certain margin from this maximum number.

It will be appreciated that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method, comprising:
storing data in a memory that includes multiple memory blocks;
estimating a level of distortion that affects a given memory block of the memory;
setting an adaptive read disturb threshold for the given memory block as a function of the estimated level of distortion; and
upon detecting that a number of read operations performed in the given memory block exceeds the read disturb threshold, copying the data stored in the memory block to an alternative storage location.

2. The method according to claim 1, wherein estimating the level of distortion comprises assessing a number of programming and erasure cycles applied to the given memory block.

3. The method according to claim 1, wherein estimating the level of distortion comprises assessing a time that elapsed since the data was stored in the given memory block.

4. The method according to claim 1, wherein detecting that the number of read operations exceeds the read disturb threshold comprises incrementing a counter for each of the read operations performed in the given memory block, and comparing the counter to the read disturb threshold.

5. The method according to claim 1, and comprising:
estimating a second level of distortion that affects a second memory block of the memory, different from the given memory block;
setting a second adaptive read disturb threshold for the second memory block depending on the estimated second level of distortion, such that the second read disturb threshold differs from the read disturb threshold of the given memory block; and
upon detecting that the number of read operations performed in the second memory block exceeds the second read disturb threshold, copying the data stored in the second memory block to a second alternative storage location.

6. The method according to claim 1, wherein setting the read disturb threshold comprises estimating a maximum number of the read operations that still enables successful readout of the stored data in the presence of the estimated level of distortion, and setting the read disturb threshold based on the maximum number.

7. The method according to claim 1, wherein detecting that the number of read operations exceeds the read disturb threshold and copying the data are performed after performing a read operation from the given memory block.

8. The method according to claim 1, wherein detecting that the number of read operations exceeds the read disturb threshold and copying the data are performed by a background task that scans the memory blocks of the memory.

9. Apparatus, comprising:
an interface, which is configured to communicate with a memory that includes multiple memory blocks; and
a processor, which is configured to store data in the memory, to estimate a level of distortion that affects a given memory block of the memory, to set an adaptive read disturb threshold for the given memory block as a function of the estimated level of distortion, and, upon detecting that a number of read operations performed in the given memory block exceeds the read disturb threshold, to copy the data stored in the memory block to an alternative storage location.

10. The apparatus according to claim 9, wherein the processor is configured to estimate the level of distortion by assessing a number of programming and erasure cycles applied to the given memory block.

11. The apparatus according to claim 9, wherein the processor is configured to estimate the level of distortion by assessing a time that elapsed since the data was stored in the given memory block.

12. The apparatus according to claim 9, wherein the processor is configured to detect that the number of read operations exceeds the read disturb threshold by incrementing a counter for each of the read operations performed in the given memory block, and comparing the counter to the read disturb threshold.

13. The apparatus according to claim 9, wherein the processor is configured to estimate a second level of distortion that affects a second memory block of the memory, different from the given memory block, to set a second adaptive read disturb threshold for the second memory block depending on the estimated second level of distortion, such that the second read disturb threshold differs from the read disturb threshold of the given memory block, and, upon detecting that the number of read operations performed in the second memory block exceeds the second read disturb threshold, to copy the data stored in the second memory block to a second alternative storage location.

14. The apparatus according to claim 9, wherein the processor is configured to estimate a maximum number of the read operations that still enables successful readout of the stored data in the presence of the estimated level of distortion, and to set the read disturb threshold based on the maximum number.

15. The apparatus according to claim 9, wherein the processor is configured to detect that the number of read operations exceeds the read disturb threshold, and to copy the data, after performing a read operation from the given memory block.

16. The apparatus according to claim 9, wherein the processor is configured to detect that the number of read operations exceeds the read disturb threshold, and to copy the data, by a background task that scans the memory blocks of the memory.

17. Apparatus, comprising:
a memory comprising multiple memory blocks; and
a processor, which is configured to store data in the memory, to estimate a level of distortion that affects a given memory block of the memory, to set an adaptive read disturb threshold for the given memory block as a function of the estimated level of distortion, and, upon detecting that a number of read operations performed in the given memory block exceeds the read disturb threshold, to copy the data stored in the memory block to an alternative storage location.

18. The apparatus according to claim 17, wherein the processor is configured to estimate the level of distortion by assessing a number of programming and erasure cycles applied to the given memory block.

19. The apparatus according to claim 17, wherein the processor is configured to estimate the level of distortion by assessing a time that elapsed since the data was stored in the given memory block.

20. The apparatus according to claim 17, wherein the processor is configured to estimate a maximum number of the read operations that still enables successful readout of the stored data in the presence of the estimated level of distortion, and to set the read disturb threshold based on the maximum number.
